(19) United States
(12) Patent Application Publication
(10) Pub. No.: US 2016/0172477 A1
(43) Pub. Date: Jun. 16, 2016

(54) METHODS TO ACHIEVE HIGH MOBILITY IN CLADDED III-V CHANNEL MATERIALS

(71) Applicant: INTEL CORPORATION, Santa Clara, CA (US)

(72) Inventors: Gilbert DEWEY, Hillsboro, OR (US); Matthew V. METZ, Portland, OR (US); Niloy MUKHERJEE, Portland, OR (US); Robert S. CHAU, Portland, OR (US); Marko RADOSAVLJEVIC, Beaverton, OR (US); Ravi PILLARISETTY, Portland, OR (US); Benjamin CHU-KUNG, Hillsboro, OR (US)

(73) Assignees: Intel Corporation, Santa Clara, CA (US); Intel Corporation, Santa Clara, CA (US)

(21) Appl. No.: 14/909,090

(22) PCT Filed: Sep. 27, 2013
(86) PCT No.: PCT/US2013/062475

§ 371 Date: Jan. 29, 2016

(51) Int. Cl. H01L 29/778; H01L 29/78; H01L 29/66; H01L 29/205

(52) U.S. Cl. CPC H01L 29/7786; H01L 29/205; H01L 29/7851; H01L 29/66462; H01L 29/66795

(57) ABSTRACT

An apparatus including a heterostructure disposed on a substrate and defining a channel region, the heterostructure including a first material having a first band gap less than a band gap of a material of the substrate and a second material having a second band gap that is greater than the first band gap; and a gate stack on the channel region, wherein the second material is disposed between the first material and the gate stack. A method including forming a first material having a first band gap on a substrate; forming a second material having a second band gap greater than the first band gap on the first material; and forming a gate stack on the second material.

### FIELD

Semiconductor devices including non-planar semiconductor devices having channel regions with low band gap cladding layers.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to optimize the performance of each device becomes increasingly significant.

Semiconductor devices formed from group III-V compound semiconductor material systems offer exceptionally high carrier mobility in the transistor channels due to low effective mass along with reduced impurity scattering. Group III and group V refer to a location of the elements of the semiconductor material in groups 13-15 of the Periodic Table of Elements (formerly groups III-V). Such devices provide high drive current performance and appear promising for future low power, high-speed logic applications. To integrate such materials on a silicon substrate, buffer layer(s) of relatively wider band gap material are typically introduced between the silicon and the group III-V compound channel material to confine carriers to the channel material and achieve short channel effects in the buffer layer(s).

### BRIEF DESCRIPTION OF THE DRAWINGS

FIG. 1 shows a top perspective view of a non-planar semiconductor device.

FIG. 2 shows an embodiment of the structure of FIG. 1 through lines 2-2′ where a cladding material in a channel includes a first group III-V compound semiconductor material and a second group III-V compound semiconductor material where there is a graded transition between the first and second group III-V compound semiconductor materials.

FIG. 3 shows an energy band for the embodiment shown in FIG. 2.

FIG. 4 shows another embodiment of the structure through line 2-2′ where a cladding material includes a first group III-V compound semiconductor material and a second group III-V compound semiconductor material where there is a stepped transition between the first and second group III-V compound semiconductor materials.

FIG. 5 shows an energy band diagram for the embodiment shown in FIG. 4.

FIG. 6 shows a graph of Hall mobility of carriers as a function of increasing indium content in InGaAs.

FIG. 7 shows the frequency dispersion of gate dielectric on indium arsenide (InAs) compared to In_{0.7}Ga_{0.3}As.

### DETAILED DESCRIPTION

One or more embodiments described herein is directed to integrating high mobility channel material on a semiconductor substrate to define a device allowing a channel material to be introduced directly on a substrate. Semiconductor devices, including group III-V compound semiconductor material are described. In one embodiment, a semiconductor device is a metal oxide semiconductor field effect transistor (MOSFET) or a microelectromechanical system (MEMS) device. Representatively, a semiconductor device is a three-dimensional MOSFET and is an isolated device or is one device in a plurality of nested devices. As will be appreciated for an integrated circuit, both N- and P-channel transistors may be fabricated on a single substrate to form a complimentary metal oxide semiconductor (CMOS) integrated circuit. Furthermore, additional interconnect may be fabricated in order to integrate such device into an integrated circuit.

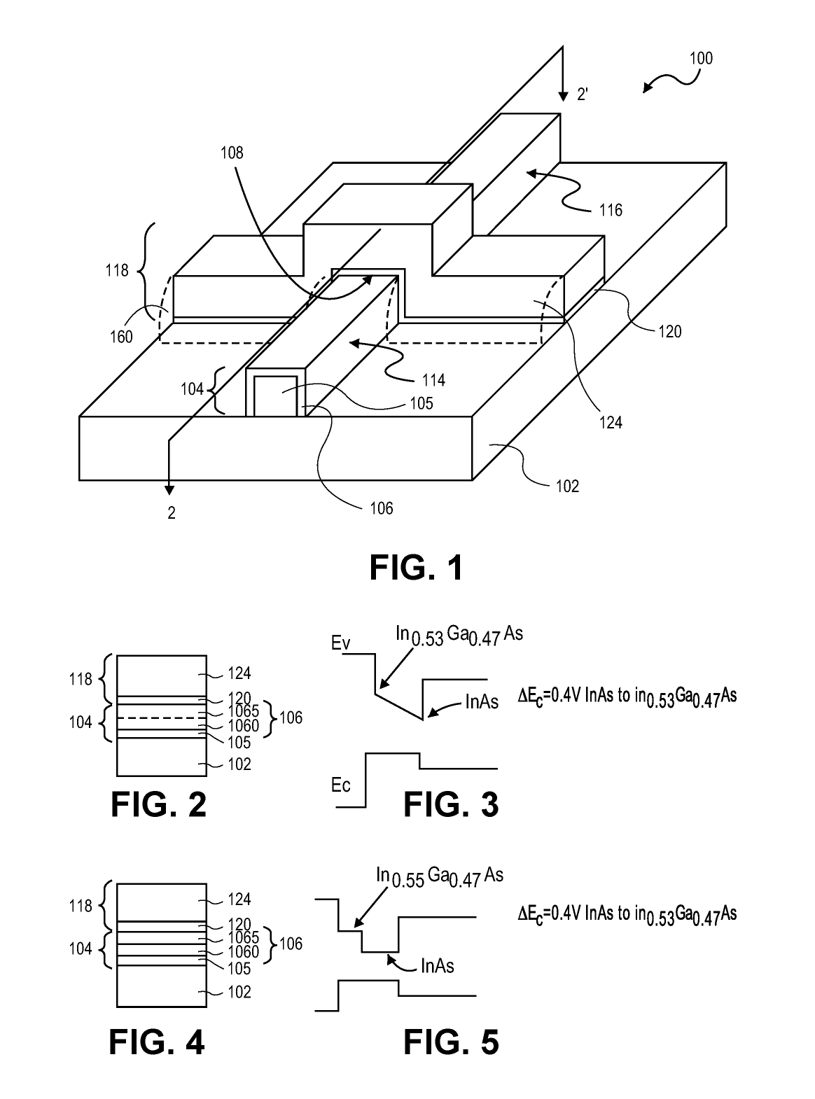

FIG. 1 shows a top perspective view of a non-planar semiconductor device. Referring to FIG. 1, structure 100 includes heterostructure 104 disposed above substrate 102. Heterostructure 104 includes core material 105 of, for example, a semiconductor material such as silicon and cladding material 106 on core material 105. In one embodiment, cladding material is a material having a different lattice spacing and a lower band gap than the core material. Representative examples are one or more group III-V compound semiconductor materials and germanium (Ge). Heterostructure 104 defines a three-dimensional body on substrate 102 and includes channel region 108. Gate stack 118 is disposed to surround at least a portion of channel region 108. Gate stack 118 includes gate electrode 124 and gate dielectric 120. In one embodiment, gate dielectric 120 is a dielectric material having a dielectric constant greater than silicon dioxide (a high K material). Examples include, but are not limited to, hafnium oxide, hafnium oxynitride, hafnium silicate, lanathanam oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof. In one embodiment, gate electrode 124 is a metal material such as, but not limited to, metal (e.g., hafnium, zirconium, tantalum, aluminum, ruthenium, palladium, platinum, cobalt, nickel), metal carbides, metal nitrides, metal silicides, metal aluminides and conductive metal oxides. Gate stack 118 may also include dielectric spacers 160. Finally, source and drain regions 114 are defined on opposite sides of channel region 108 (outside gate stack 118) and heterostructure 104.

Substrate 102 may be representatively composed of a material suitable for semiconductor device fabrication. In one embodiment, substrate 102 is a bulk substrate composed of a single crystal material which may include, but is not limited to, silicon or germanium. In another embodiment, substrate 102 includes a bulk layer with a top epitaxial layer (as viewed). In a specific embodiment, the bulk layer is composed of a single crystal material which may include, for example, silicon or germanium, while the top layer is composed of a single crystal that may include, but is not limited to, silicon, germanium, silicon-germanium or a group III-V compound semiconductor material. In another embodiment, substrate 102 includes a top epitaxial layer on an insulated layer which is above a lower bulk layer. The top epitaxial layer is composed of a single crystal layer that may include, but is not limited to, silicon (e.g., a silicon-on-insulator (SOI) semiconductor substrate). A representative insulator layer includes, but is not limited to, silicon dioxide. The lower bulk layer may be composed of a single crystal layer which may include, but is not limited to, silicon or germanium.

In one embodiment, heterostructure 104 includes core material 105. In one embodiment, core material 105 is a single crystal semiconductor material such as silicon introduced to a thickness on the order of less than five nanometers, for example, two to three nanometers. In this manner, core material 105 will comply with a lattice structure of a cladding material introduced thereon. For example, core material 105 will stretch or be flexible enough to accommodate a cladding material having a larger lattice structure than a lattice structure of core material 105. Generally, when a lattice mismatched material is grown on a bulk substrate all or most of the strain developed during the growth due to lattice mismatch falls across the growth material. If the grown material or in the instant case, core material 105 is thinned in such a way that it is a nanostructure or otherwise extremely thin, then it can be considered a compliant core when during subsequent growth of a lattice mismatched material on the core, some or most of the strain is dissipated across the core material because it is close to the same thickness or thinner than the material grown on the core material.

Overlying core material 105 in structure 100 of FIG. 1 is cladding material 106. In one embodiment, cladding material 106 is composed of multiple group III-V compound semiconductor materials introduced to a thickness to be compliant with core material 105. Representatively, to better nucleate the group III-V compound semiconductor material growth on a core material of a single crystal semiconductor such as silicon, a binary group III-V compound semiconductor material with high mobility and relatively low band gap is introduced on the core material and a second group III-V compound semiconductor material, such as a ternary group III-V material such as a ternary group III-V compound semiconductor material is introduced on the first group III-V compound semiconductor material, where the second group III-V compound semiconductor material has a larger band gap than the first but has a property to better interact with a gate dielectric (e.g., gate dielectric 120) than the first group III-V compound semiconductor material. The illustrations of core material 105 and cladding material 106 in FIG. 1 are only illustrations of the materials and are not meant to imply a relationship between the thicknesses. Similarly, it is appreciated that in fabricating a structure such as structure 100, generally available tooling may not be capable of producing clean, defined edges such as illustrated and transitions may, for example, be more rounded.

FIG. 2 shows an embodiment of the structure of FIG. 1 through lines 2-2′. FIG. 2 shows heterostructure 104 disposed on substrate 102 and gate stack 118 disposed on heterostructure 104. FIG. 2 shows a portion of the structure representatively associated with channel region 108 (see FIG. 1). Referring to heterostructure 104, in one embodiment, heterostructure 104 includes core material 105 of, for example, silicon. In an embodiment, where structure 100 defines an N-type three-dimensional transistor device, in one embodiment, cladding material 106 includes first cladding material 1060 of, for example, a binary group III-V material such as indium arsenide (InAs) having a representative thickness on the order of 3 nanometers (nm) to 15 nm. InAs nucleates well on silicon and has a lower band gap and higher mobility. Overlying first cladding material 1060 of InAs is second group III-V compound semiconductor material of, for example, indium gallium arsenide (InGaAs). InGaAs has a higher band gap than InAs on the substrate. In the embodiment shown in FIG. 2, gallium is introduced at greater percentages to grade the transition from InAs to In_{0.53}Ga_{0.47}As. Second cladding material 1065 represents each transition from InAs (cladding material 1060) to, in one embodiment, In_{0.53}Ga_{0.47}As. In this embodiment, the transition is graded in the sense that the gallium concentration in second cladding material is gradually increased from zero percent at the interface of core material 105 to 47 percent at the interface of gate dielectric 120. Increasing the amount of gallium and decreasing the amount of indium tends to confine carriers (e.g., electrons) to first cladding material 1060 and tends to improve the interaction of the group III-V compound semiconductor material with a gate dielectric interface (gate dielectric 120). The use of different layers enables the last layer to be selected or engineered such that gate dielectric compatibility can be maximized.

FIG. 3 shows an energy band for an embodiment where cladding material 106 is graded from, for example, InAs to In_{0.53}Ga_{0.47}As to confine carriers to the high mobility InAs and to interact with gate dielectric 120. As illustrated in FIG. 3, the lowest energy state exists where the group III-V compound semiconductor material is 100 percent indium (InAs). Carriers (e.g., electrons) will seek and be confined at the lowest energy state. As gallium is introduced into the group III-V compound semiconductor material, the energy level increases. FIG. 3 shows the gradation going from 100 percent indium to 53 percent indium and 47 percent gallium (In_{0.53}Ga_{0.47}As). Since the carriers are confined to lowest energy state (InAs), the carriers are confined away from the dielectric material (dielectric layer 120, FIG. 2) and therefore tend to have a higher mobility. Further, an advantage of using a binary material such as InAs in direct contact with a material such as silicon (core material 105) is that the binary group III-V material tends to nucleate on silicon more readily then a ternary material might otherwise nucleate.

FIG. 4 shows another embodiment of structure 100 through line 2-2′ of structure 100. FIG. 4 shows heterostructure 104 disposed on substrate 102 and gate stack 118 on heterostructure 104. Heterostructure 104 includes, in this embodiment, two materials: A first material having a low band gap and a second material having a relatively higher band gap compared to the first material. For an N-type device, material 1060 is a binary group III-V compound semiconductor material such as InAs and material 1065 is a ternary group III-V material such as In_{0.53}Ga_{0.47}As. In the embodiment shown in FIG. 4, the transition from first material 1060 (e.g., 100 percent indium in InAs) to second material 1065 (e.g., a material with a smaller percentage of indium that interacts well with a gate dielectric) is stepped. FIG. 5 shows an energy band diagram or the configurations described in FIG. 4. In this embodiment, the lowest energy state is again the 100 percent indium (InAs) and the carriers will be confined there away from the gate dielectric and at increased mobility. In one sense, the InGaAs with some percentage of gallium (Inₒ₅₃Ga_{0.47}As) acts as a cap on the carrier material (InAs) to interact with a gate dielectric and contain the carriers within the high mobility material.

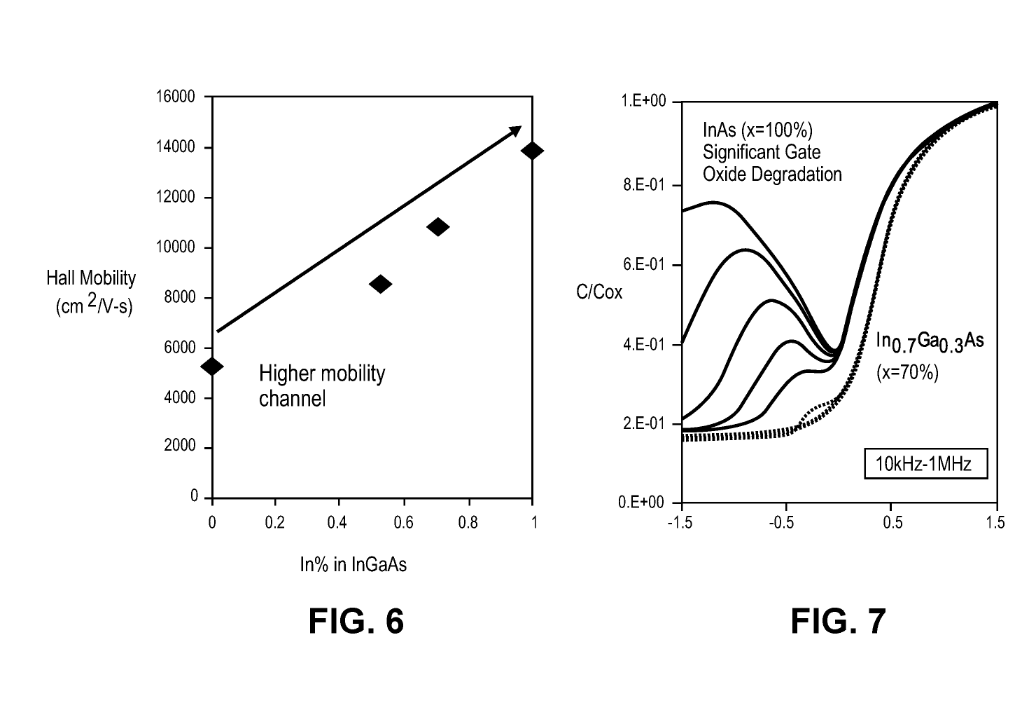

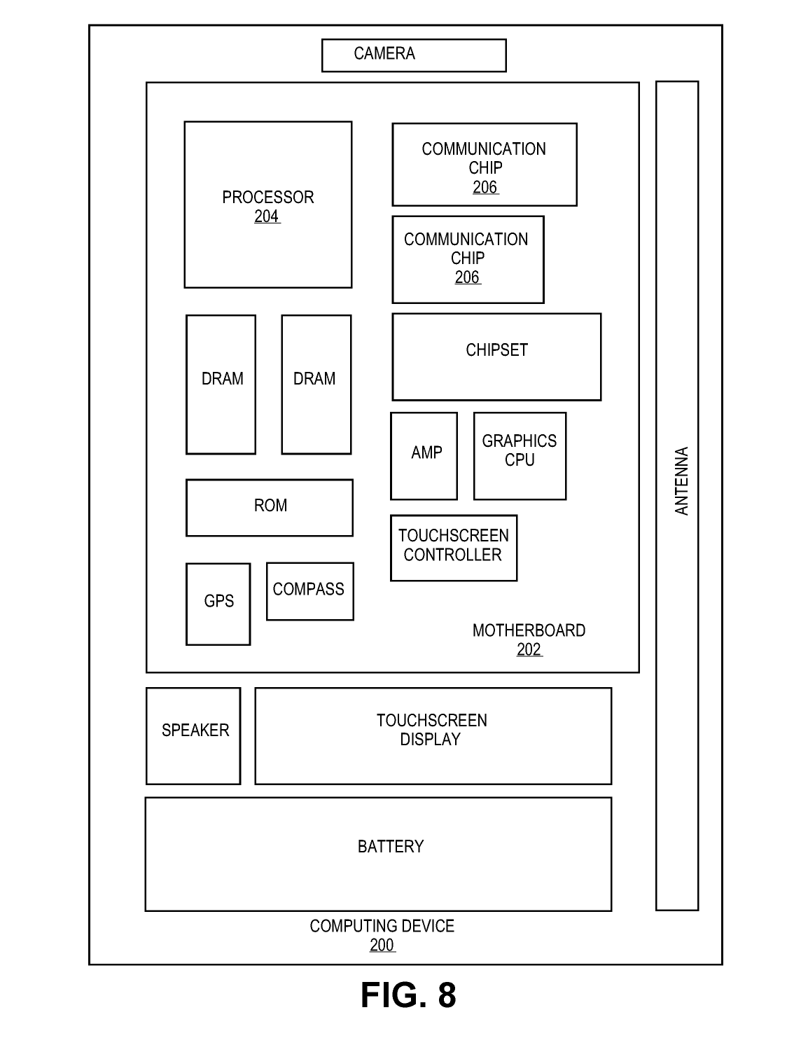

FIG. 6 shows a graph of Hall mobility of carriers as a function of increasing indium content in InGaAs. As illustrated in FIG. 6, the highest mobility occurs in InAs (100 percent In). FIG. 7 shows the frequency dispersion of gate dielectric on indium arsenide (InAs) compared to In_{0.7}Ga_{0.3}As. The relatively smooth line of the In_{0.7}Ga_{0.3}As indicates improved interaction with gate dielectric and avoidance of defects that can act like scattering sites.

The above-described embodiment related to a three-dimensional N-type structure incorporating a high mobility material grown directly on a silicon core material via cladding. It is appreciated that a cladding technique is one representation technique and others may also be utilized including, but not limited to, aspect ratio trapping where, for example, a fin is carved out of silicon and a group III-V compound semiconductor material is formed in or out of the fin. It is appreciated that the teachings will apply to other device structures, including but not limited to, two-dimensional devices and nanowire devices. Further, one example was directed to N-type devices and the use of InGaAs and InAs. It is appreciated that similar principles may be applied for other group III-V materials and for N- and P-types devices (e.g., Ge, InSb, GaAsSb, GaSb, etc.). For example, Ge and Ge/Si may be utilized in a similar fashion, such as in a P-type device and grading or stepping an amount of germanium relative to a thin silicon film (nanoscale silicon).

FIG. 8 illustrates a computing device 200 in accordance with one implementation. Computing device 200 houses board 202. Board 202 may include a number of components, including but not limited to processor 204 and at least one communication chip 206. Processor 204 is physically and electrically coupled to board 202. In some implementations at least one communication chip 206 is also physically and electrically coupled to board 202. In further implementations, communication chip 206 is part of processor 204.

Depending on its applications, computing device 200 may include other components that may or may not be physically and electrically coupled to board 202. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 206 enables wireless communications for the transfer of data to and from computing device 200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 206 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 200 may include a plurality of communication chips 206. For instance, first communication chip 206 may be dedicated to shorter range wireless communications such as Wi-Fi and Bluetooth and second communication chip 206 may be dedicated to longer range wireless communications such as GPS, EDGE, GPRS, CDMA, WiMAX, LTE, Ev-DO, and others.

Processor 204 of computing device 200 includes an integrated circuit die packaged within processor 204. In some implementations of the invention, the integrated circuit die of the processor includes one or more devices, such as MOSFET transistors built in accordance with implementations of the invention. The term “processor” may refer to any device or portion of a device that processes electronic data from registers and/or memory to transform that electronic data into other electronic data that may be stored in registers and/or memory.

Communication chip 206 also includes an integrated circuit die packaged within communication chip 206. In accordance with another implementation of the invention, the integrated circuit die of the communication chip includes one or more devices, such as MOSFET transistors built in accordance with implementations of the invention.

In further implementations, another component housed within computing device 200 may contain an integrated circuit die that includes one or more devices, such as MOSFET transistors built in accordance with implementations of the invention.

In various implementations, computing device 200 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 200 may be any other electronic device that processes data.

### Examples

Example 1 is a semiconductor apparatus including a heterostructure disposed on a substrate and defining a channel region, the heterostructure including a first material having a first band gap less than a band gap of a material of the substrate and a second material having a second band gap that is greater than the first band gap; and a gate stack on the channel region, the gate stack including a dielectric material and a gate electrode on the dielectric material, wherein the second material is disposed between the first group III-V material and the gate stack.

In Example 2, the first material of the semiconductor apparatus of Example 1 includes a binary group III-V semiconductor material.

In Example 3, the first material of the semiconductor apparatus of Example 2 includes InAs.

In Example 4, the second material of the semiconductor apparatus of Example 1 is a ternary group III-V semiconductor material.

In Example 5, a transition between the first material and the second material in the semiconductor apparatus of Example 1 is graded.

In Example 6, a transition between the first material and the second material in the semiconductor apparatus of Example 1 is stepped.

In Example 7, the first material of the semiconductor apparatus of Example 1 includes InAs and the second material comprises InGaAs.

Example 8 is a method of forming a semiconductor device including forming a first material having a first band gap on a substrate, the first band gap less than a band gap of a material of the substrate; forming a second group III-V material having a second band gap greater than the first band gap on the first binary group III-V material; and forming a gate stack on the second group III-V material.

In Example 9, the first group III-V material in the method of Example 8 includes a binary group III-V material.

In Example 10, the first group III-V material in the method of Example 8 is InAs.

In Example 11, the second group III-V material in the method of Example 8 is a ternary group III-V material.

In Example 12, a transition between the first group III-V material and the second group III-V material in the method of Example 8 is graded.

In Example 13, a transition between the first binary group III-V material and the second group III-V material in the method of Example 8 is stepped.

Example 14 is a semiconductor device formed by any of the methods of Examples 8-13.

Example 15 is a semiconductor apparatus including a transistor on a substrate, the transistor comprising a channel region on a portion of the substrate; a first material having a first band gap less than a band gap of the semiconductor material of the substrate and a second material having a second band gap that is greater than the first band gap; and a gate stack on the channel region, the gate stack comprising a dielectric material a gate electrode on the dielectric material, wherein the portion of the substrate associated with the channel region has a property to comply with a lattice structure of the first material.

In Example 16, the first material of the semiconductor apparatus of Example 15 includes a binary group III-V semiconductor material.

In Example 17, the first material of the semiconductor apparatus of Example 15 includes InAs.

In Example 18, the second material of the semiconductor apparatus of Example 15 is a ternary group III-V semiconductor material.

In Example 19, a transition between the first material and the second material of the semiconductor apparatus of Example 15 is graded.

In Example 20, a transition between the first material and the second material of the semiconductor apparatus of Example 15 is stepped.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

1. A semiconductor apparatus comprising:
a heterostructure disposed on a substrate and defining a channel region, the heterostructure comprising a first material having a first band gap less than a band gap of a material of the substrate and a second material having a second band gap that is greater than the first band gap; and
a gate stack on the channel region, the gate stack comprising a dielectric material and a gate electrode on the dielectric material,
wherein the second material is disposed between the first group III-V material and the gate stack.

2. The apparatus of claim 1, wherein the first material comprises a binary group III-V semiconductor material.

3. The apparatus of claim 2, wherein the first material comprises InAs.

4. The apparatus of claim 1, wherein the second material is a ternary group III-V semiconductor material.

5. The apparatus of claim 1, wherein a transition between the first material and the second material is graded.

6. The apparatus of claim 1, wherein a transition between the first material and the second material is stepped.

7. The apparatus of claim 1, wherein the first material comprises InAs and the second material comprises InGaAs.

8. A method of forming a semiconductor device comprising:
forming a first material having a first band gap on a substrate, the first band gap less than a band gap of a material of the substrate;
forming a second group III-V material having a second band gap greater than the first band gap on the first binary group III-V material; and
forming a gate stack on the second group III-V material.

9. The method of claim 8, wherein the first group III-V material comprises a binary group III-V material.

10. The method of claim 9, wherein the first group III-V material is InAs.

11. The method of claim 8, wherein the second group III-V material is a ternary group III-V material.

12. The method of claim 8, wherein a transition between the first group III-V material and the second group III-V material is graded.

13. The method of claim 8, wherein a transition between the first binary group III-V material and the second group III-V material is stepped.

14. (canceled)

15. A semiconductor apparatus comprising:
a transistor on a substrate, the transistor comprising a channel region on a portion of the substrate;
a first material having a first band gap less than a band gap of the semiconductor material of the substrate and a second material having a second band gap that is greater than the first band gap; and
a gate stack on the channel region, the gate stack comprising a dielectric material a gate electrode on the dielectric material,
wherein the portion of the substrate associated with the channel region has a property to comply with a lattice structure of the first material.

16. The apparatus of claim 14, wherein the first material comprises a binary group III-V semiconductor material.

17. The apparatus of claim 15, wherein the first material comprises InAs.

18. The apparatus of claim 14, wherein the second material is a ternary group III-V semiconductor material.

19. The apparatus of claim 14, wherein a transition between the first material and the second material is graded.

20. The apparatus of claim 14, wherein a transition between the first material and the second material is stepped.
